(19) United States
(12) Patent Application Publication
(10) Pub. No.: US 2026/0066606 A1
(43) Pub. Date: Mar. 5, 2026

(54) GAS LASER DEVICE AND ELECTRONIC DEVICE MANUFACTURING METHOD

(71) Applicant: Gigaphoton Inc., Tochigi (JP)

(72) Inventors: Tokinori TERAO, Tochigi (JP); Masakazu HATTORI, Tochigi (JP); Tatsuo YAMAGUCHI, Tochigi (JP); Hirotaka MIYAMOTO, Tochigi (JP)

(73) Assignee: Gigaphoton Inc., Tochigi (JP)

(21) Appl. No.: 19/380,930

(22) Filed: Nov. 5, 2025

Related U.S. Application Data
(63) Continuation of application No. PCT/JP2023/020880, filed on Jun. 5, 2023.

(51) Int. Cl. H01S 3/08; G02B 27/09; G03F 7/00; H01S 3/034; H01S 3/10; H01S 3/23

(52) U.S. Cl. CPC H01S 3/08059; G02B 27/0983; G03F 7/70025; G03F 7/70041; H01S 3/034; H01S 3/10061; H01S 3/2308; H01S 3/2366

(57) ABSTRACT

A gas laser device amplifies, using an amplifier, laser light output from a laser oscillator. The amplifier includes a chamber device, a resonator including an output coupling mirror and causing the laser light to resonate, a polarizer reducing linear polarization whose polarization direction is different from a polarization direction of a first linear polarization, and a beam expander. The beam expander includes a convex mirror including a reflection surface on which the laser light output from the chamber device is incident and which reflects the laser light so that a beam width of the laser light is expanded, and a concave mirror including a reflection surface on which the laser light reflected by the convex mirror is incident and which reflects the laser light toward the output coupling mirror so as to collimate the laser light so that the expanded beam width of the laser light becomes constant.

### CROSS-REFERENCE TO RELATED APPLICATIONS

The present application is a continuation application of International Application No. PCT/JP2023/020880, filed on Jun. 5, 2023, the entire contents of which are hereby incorporated by reference.

### BACKGROUND

### 1. Technical Field

The present disclosure relates to a gas laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248.0 nm and an ArF excimer laser device for outputting laser light having a wavelength of about 193.4 nm are used.

The KrF excimer laser device and the ArF excimer laser device each have a large spectral line width of about 350 μm to 400 μm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to line-narrow a spectral line width. In the following, a gas laser device with a narrowed spectral line width is referred to as a line narrowing gas laser device.

### LIST OF DOCUMENTS

### Patent Documents

Patent Document 1: Japanese Patent Application Publication No. 2011-233918
Patent Document 2: Japanese Patent Application Publication No. H4-239784
Patent Document 3: Japanese Patent Application Publication No. H4-301613
Patent Document 4: US Patent Application Publication No. 2020/0393687

### SUMMARY

A gas laser device according to an aspect of the present disclosure is configured to amplify, using an amplifier, laser light output from a laser oscillator and output the laser light. Here, the amplifier includes a chamber device including a pair of discharge electrodes facing each other and arranged at an internal space thereof through which the laser light from the laser oscillator passes and in which a laser gas is filled, and configured to amplify the laser light from the laser oscillator by a voltage being applied between the pair of discharge electrodes; a resonator configured to cause the laser light output from the chamber device to resonate between both sides sandwiching the chamber device; a polarizer arranged on an optical path of the laser light of the resonator, and configured to reduce, from the laser light, linear polarization whose polarization direction is different from a polarization direction of a first linear polarization; and a beam expander. The resonator includes an output coupling mirror arranged on one side of the sides sandwiching the chamber device, and is configured to cause a part of the laser light output from the chamber device to be transmitted therethrough, and another part of the laser light output from the chamber device to be reflected to return into the chamber device. The beam expander is arranged between the chamber device and the output coupling mirror, and includes a convex mirror including a reflection surface on which the laser light output from the chamber device is incident so that the first linear polarization in the laser light becomes S-polarization, and which reflects the laser light so that a beam width of the laser light is expanded; and a concave mirror including a reflection surface on which the laser light reflected by the convex mirror is incident so that the first linear polarization in the laser light becomes S-polarization, and which reflects the laser light toward the output coupling mirror so as to collimate the laser light so that the expanded beam width of the laser light becomes constant.

An electronic device manufacturing method according to an aspect of the present disclosure includes generating pulse laser light using a gas laser device, outputting the pulse laser light to an exposure apparatus, and exposing a photosensitive substrate to the pulse laser light in the exposure apparatus to manufacture an electronic device. Here, the gas laser device is configured to amplify, using an amplifier, laser light output from a laser oscillator and output the laser light. The amplifier includes a chamber device including a pair of discharge electrodes facing each other and arranged at an internal space thereof through which the laser light from the laser oscillator passes and in which a laser gas is filled, and configured to amplify the laser light from the laser oscillator by a voltage being applied between the pair of discharge electrodes; a resonator configured to cause the laser light output from the chamber device to resonate between both sides sandwiching the chamber device; a polarizer arranged on an optical path of the laser light of the resonator, and configured to reduce, from the laser light, linear polarization whose polarization direction is different from a polarization direction of a first linear polarization; and a beam expander. The resonator includes an output coupling mirror arranged on one side of the sides sandwiching the chamber device, and configured to cause a part of the laser light output from the chamber device to be transmitted therethrough, and another part of the laser light output from the chamber device to be reflected to return into the chamber device. The beam expander is arranged between the chamber device and the output coupling mirror, and includes a convex mirror including a reflection surface on which the laser light output from the chamber device is incident so that the first linear polarization in the laser light becomes S-polarization, and which reflects the laser light so that a beam width of the laser light is expanded; and a concave mirror including a reflection surface on which the laser light reflected by the convex mirror is incident so that the first linear polarization in the laser light becomes S-polarization, and which reflects the laser light toward the output coupling mirror so as to collimate the laser light so that the expanded beam width of the laser light becomes constant.

### BRIEF DESCRIPTION OF THE DRAWINGS

Embodiments of the present disclosure will be described below merely as examples with reference to the accompanying drawings.

FIG. 1 is a schematic view showing a schematic configuration example of an entire electronic device manufacturing apparatus.

FIG. 2 is a schematic view showing a schematic configuration example of an entire gas laser device of a comparative example.

FIG. 3 is a schematic view showing a schematic configuration example of an amplifier of a first embodiment.

FIG. 4 is a schematic view showing a schematic configuration example of a beam expander.

FIG. 5 is a perspective view showing a convex mirror and a concave mirror according to the first embodiment.

FIG. 6 is a sectional view of the convex mirror.

FIG. 7 is a sectional view of the concave mirror.

FIG. 8 is a schematic view showing a schematic configuration example of the amplifier of a modification of the first embodiment in a similar manner to FIG. 3.

FIG. 9 is a schematic view showing a schematic configuration example of the amplifier of a second embodiment in a similar manner to FIG. 3.

FIG. 10 is a schematic view showing a schematic configuration example of the beam expander of the second embodiment in a similar manner to FIG. 4.

FIG. 11 is a perspective view showing the convex mirror, a planar mirror, and the concave mirror of the second embodiment in a similar manner to FIG. 5.

FIG. 12 is a schematic view showing a schematic configuration example of the amplifier of a third embodiment in a similar manner to FIG. 3.

FIG. 13 is a schematic view showing a schematic configuration example of the beam expander of the third embodiment in a similar manner to FIG. 4.

FIG. 14 is a perspective view showing the convex mirror, two planar mirrors, and the concave mirror of the third embodiment in a similar manner to FIG. 5.

### DESCRIPTION OF EMBODIMENTS

1. Description of electronic device manufacturing apparatus used in exposure process for electronic device
2. Description of gas laser device of comparative example
   2.1 Configuration
   2.2 Operation
   2.3 Problem
3. Description of gas laser device of first embodiment
   3.1 Configuration
   3.2 Operation
   3.3 Effect
   3.4 Modification
4. Description of gas laser device of second embodiment
   4.1 Configuration
   4.2 Operation
   4.3 Effect
5. Description of gas laser device of third embodiment
   5.1 Configuration
   5.2 Operation
   5.3 Effect

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Description of Electronic Device Manufacturing Apparatus Used in Exposure Process for Electronic Device

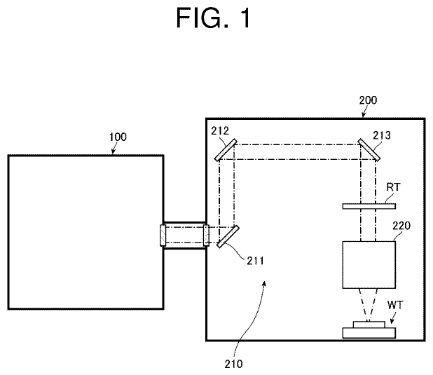

FIG. 1 is a schematic view showing a schematic configuration example of an entire electronic device manufacturing apparatus used in an exposure process for an electronic device. As shown in FIG. 1, the manufacturing apparatus used in the exposure process includes a gas laser device 100 and an exposure apparatus 200. The exposure apparatus 200 includes an illumination optical system 210 including a plurality of mirrors 211, 212, 213 and a projection optical system 220. The illumination optical system 210 illuminates a reticle pattern of a reticle stage RT with laser light entering from the gas laser device 100. The projection optical system 220 causes the laser light transmitted through the reticle to be imaged as being reduced and projected on a workpiece (not shown) arranged on a workpiece table WT. The workpiece is a photosensitive substrate such as a semiconductor wafer on which photoresist is applied. The exposure apparatus 200 synchronously translates the reticle stage RT and the workpiece table WT to expose the workpiece to the laser light reflecting the reticle pattern. Through the exposure process as described above, a device pattern is transferred onto the semiconductor wafer, thereby a semiconductor device, which is the electronic device, can be manufactured.

### 2. Description of Gas Laser Device of Comparative Example

### 2.1 Configuration

The gas laser device of a comparative example will be described. The comparative example of the present disclosure is an example recognized by the applicant as known only by the applicant, and is not a publicly known example admitted by the applicant.

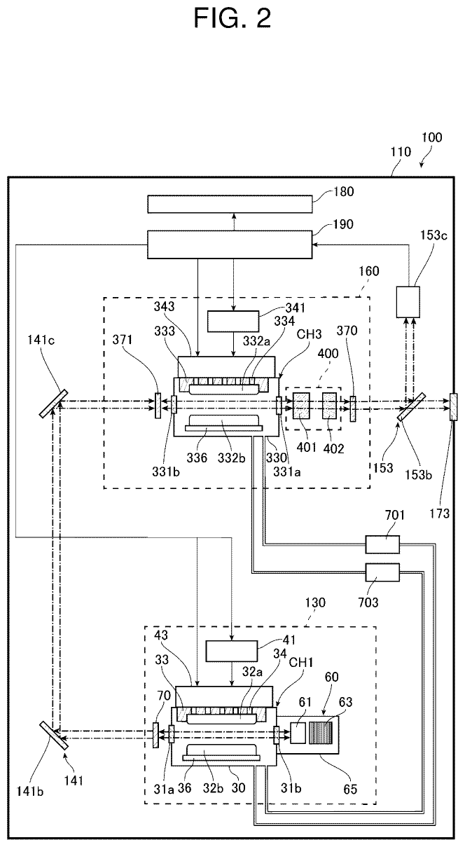

FIG. 2 is a schematic view showing a schematic configuration example of the entire gas laser device 100 of the present example. The gas laser device 100 is, for example, an ArF excimer laser device using a mixed gas including argon (Ar), fluorine (F₂), and neon (Ne). The gas laser device 100 outputs laser light having a center wavelength of about 193.4 nm. Here, the gas laser device 100 may be a gas laser device other than the ArF excimer laser device, and may be, for example, a KrF excimer laser device using a mixed gas including krypton (Kr), F₂, and Ne. In this case, the gas laser device 100 outputs laser light having a center wavelength of about 248.0 nm. The mixed gas containing Ar, F₂, and Ne which is a laser medium and the mixed gas containing Kr, F₂, and Ne which is a laser medium may be each referred to as a laser gas. In the mixed gas used in each of the ArF excimer laser device and the KrF excimer laser device, helium (He) may be used instead of Ne.

The gas laser device 100 of the present example includes a housing 110, a laser oscillator 130 that is a master oscillator arranged at the internal space of the housing 110, an optical transmission unit 141, an amplifier 160 that is a power oscillator, a detection unit 153, a display unit 180, a processor 190, a laser gas exhaust device 701, and a laser gas supply device 703 as a main configuration.

The laser oscillator 130 includes a chamber device CH1, a charger 41, a pulse power module 43, a line narrowing module 60, and an output coupling mirror 70 as a main configuration.

In FIG. 2, the internal configuration of the chamber device CH1 is shown as viewing from a direction substantially perpendicular to the travel direction of the laser light. The chamber device CH1 includes a housing 30, a pair of windows 31a, 31b, a pair of electrodes 32a, 32b, an insulating portion 33, a feedthrough 34, and an electrode holder portion 36 as a main configuration.

The housing 30 is supplied with the laser gas from the laser gas supply device 703 to the internal space of the housing 30 via a pipe, and the internal space is filled with the laser gas. The internal space is a space in which light is generated by excitation of the laser medium in the laser gas. This light travels to the windows 31a, 31b.

The window 31a is arranged at a wall surface of the housing 30 on the front side in the travel direction of the laser light from the gas laser device 100 to the exposure apparatus 200, and the window 31b is arranged at a wall surface of the housing 30 on the rear side in the travel direction. The windows 31a, 31b are calcium fluoride substrates, and surfaces of the windows 31a, 31b on the inner side and the outer side of the housing 30 are flat surfaces. Here, the windows 31a, 31b are not limited to the calcium fluoride substrate as long as being capable of transmitting the laser light.

The electrodes 32a, 32b are arranged to face each other at the internal space of the housing 30, and the longitudinal direction of the electrodes 32a, 32b is along the travel direction of the light generated by the high voltage applied between the electrode 32a and the electrode 32b. The space between the electrode 32a and the electrode 32b in the housing 30 is sandwiched by the window 31a and the window 31b. The electrodes 32a, 32b are discharge electrodes for exciting the laser medium by glow discharge. In the present example, the electrode 32a is the cathode and the electrode 32b is the anode.

The electrode 32a is supported by the insulating portion 33. The insulating portion 33 blocks an opening formed in the housing 30. The insulating portion 33 includes an insulator. Further, the feedthrough 34 made of a conductive member is arranged in the insulating portion 33. The feedthrough 34 applies a voltage, to the electrode 32a, supplied from the pulse power module 43. The electrode 32b is supported by the electrode holder portion 36 and is electrically connected to the electrode holder portion 36.

The charger 41 is a DC power source device that charges a capacitor (not shown) provided in the pulse power module 43 with a predetermined voltage. The charger 41 is arranged outside the housing 30 and is connected to the pulse power module 43. The pulse power module 43 includes a switch (not shown) controlled by the processor 190. The pulse power module 43 is a voltage application circuit that, when the switch is turned ON from OFF by the control, boosts the voltage applied from the charger 41 to generate a pulse high voltage, and applies the high voltage to the electrodes 32a, 32b. When the high voltage is applied, discharge occurs between the electrode 32a and the electrode 32b. The energy of the discharge excites the laser medium in the housing 30. When the excited laser gas shifts to a ground level, light is emitted, and the emitted light is transmitted through the windows 31a, 31b and is output to the outside of the housing 30. The windows 31a, 31b are inclined at the Brewster angle with respect to the travel direction of the laser light so that P-polarized light of the laser light is suppressed from being reflected. In the present example, the windows 31a, 31b are inclined with respect to a direction perpendicular to the travel direction of the laser light and to a direction in which the electrodes 32a, 32b face each other. Therefore, the laser light output from the chamber device CH1 includes first linear polarization whose polarization direction is perpendicular to the direction in which the electrodes 32a, 32b face each other, and linear polarization whose polarization direction is different from the polarization direction of the first linear polarization is reduced from the laser light. That is, each of the windows 31a, 31b also serves as a polarizer that is inclined with respect to the polarization direction of the first linear polarization and reduces, from the laser light, the linear polarization whose polarization direction is different from the polarization direction of the first linear polarization.

In the present specification and claims, the term “perpendicular” refers to a state in which the angle formed is 85 degrees or more and 95 degrees or less, and the term “parallel” refers to a state in which the angle formed is 5 degrees or less.

The line narrowing module 60 includes a housing 65, and a prism 61, a grating 63, and a rotation stage (not shown) arranged at the internal space of the housing 65. An opening is formed in the housing 65, and the housing 65 is connected to the rear side of the housing 30 via the opening.

The prism 61 expands the beam width of the light output from the window 31b and causes the light to be incident on the grating 63. The prism 61 also reduces the beam width of the light reflected from the grating 63 and returns the light to the internal space of the housing 30 via the window 31b. The prism 61 is supported by the rotation stage and is rotated by the rotation stage. The incident angle of the light with respect to the grating 63 is changed by the rotation of the prism 61. Therefore, by rotating the prism 61, the wavelength of the light returning from the grating 63 to the housing 30 via the prism 61 can be selected. Although FIG. 2 shows an example in which one prism 61 is arranged, two or more prisms may be arranged.

The surface of the grating 63 is configured of a material having a high reflectance, and a large number of grooves are formed on the surface at predetermined intervals. The grating 63 is a dispersive optical element. The sectional shape of each groove is, for example, a right-angled triangle. The light incident on the grating 63 from the prism 61 is reflected by these grooves and diffracted in a direction corresponding to the wavelength of the light. The grating 63 is arranged in the Littrow arrangement, which causes the incident angle of the light incident on the grating 63 from the prism 61 to coincide with the diffraction angle of the diffracted light having a desired wavelength. Thus, light having a desired wavelength returns to the housing 30 via the prism 61.

The output coupling mirror 70 faces the window 31a, transmits a part of the laser light output from the window 31a, and reflects another part thereof to return to the internal space of the housing 30 via the window 31a. The output coupling mirror 70 is fixed to a holder (not shown) and is arranged at the internal space of the housing 110.

The grating 63 and the output coupling mirror 70 arranged with the housing 30 interposed therebetween configure a Fabry-Perot resonator, and the housing 30 is arranged on the optical path of the resonator.

Accordingly, the resonator causes the light to resonate between both sides sandwiching the chamber device CH1. The optical transmission unit 141 includes high reflection mirrors 141b, 141c as a main configuration. The high reflection mirrors 141b, 141c are respectively fixed to holders (not shown) with inclination angles thereof adjusted, and are arranged at the internal space of the housing 110. The high reflection mirrors 141b, 141c highly reflect the laser light. The high reflection mirrors 141b, 141c are arranged on the optical path of the laser light from the output coupling mirror 70. The laser light is reflected by the high reflection mirrors 141b, 141c and travels to a rear mirror 371 of the amplifier 160. At least a part of the laser light is transmitted through the rear mirror 371.

The amplifier 160 amplifies the energy of the laser light output from the laser oscillator 130. The basic configuration of the amplifier 160 is substantially the same as that of the laser oscillator 130. In order to distinguish the components of the amplifier 160 from the components of the laser oscillator 130, the chamber device, the housing, the pair of windows, the pair of electrodes, the insulating portion, the feedthrough, the electrode holder portion, the charger, the pulse power module, and the output coupling mirror of the amplifier 160 are described as a chamber device CH3, a housing 330, a pair of windows 331a, 331b, a pair of electrodes 332a, 332b, an insulating portion 333, a feedthrough 334, an electrode holder portion 336, a charger 341, a pulse power module 343, and an output coupling mirror 370. The electrodes 332a, 332b cause discharge for amplifying the laser light from the laser oscillator 130. The direction in which the electrodes 332a, 332b face each other is a direction perpendicular to the polarization direction of the first linear polarization in the laser light from the laser oscillator 130. The windows 331a, 331b are inclined with respect to the polarization direction of the first linear polarization so that the first linear polarization in the laser light is incident thereon as P-polarized light and an incident angle θ of the laser light becomes the Brewster angle. Therefore, the laser light output from the chamber device CH3 includes first linear polarization, and linear polarization whose polarization direction is different from the first linear polarization is reduced from the laser light. That is, similarly to the windows 31a, 31b, each of the windows 331a, 331b also serves as a polarizer that is inclined with respect to the polarization direction of the first linear polarization and reduce, from the laser light, the linear polarization whose polarization direction is different from the polarization direction of the first linear polarization. Similarly to the pulse power module 43, the pulse power module 343 is a voltage application circuit.

The amplifier 160 is mainly different from the laser oscillator 130 in that the line narrowing module 60 is not included and the rear mirror 371 and a beam expander 400 are included.

The rear mirror 371 is provided between the high reflection mirror 141c and the window 331b and faces to both thereof. The rear mirror 371 transmits a part of the laser light from the laser oscillator 130 toward the space between the electrodes 332a, 332b, and reflects a part of the laser light amplified by the electrodes 332a, 332b toward the space between the electrodes 332a, 332b.

The output coupling mirror 370 is arranged on a side opposite to the rear mirror 371 with respect to the chamber device CH3, and the beam expander 400 is arranged between the chamber device CH3 and the output coupling mirror 370. The beam expander 400 of the present example includes two prisms 401, 402. The prism 401 expands the beam width of the laser light output from the chamber device CH3. The prism 402 further expands the beam width of the light whose beam width has been expanded by the prism 401, and outputs the light toward the output coupling mirror 370. Further, the prism 402 reduces the beam width of the reflection light from the output coupling mirror 370, and the prism 401 further reduces the beam width of the light whose beam width has been reduced by the prism 402, and returns the light to the internal space of the housing 330 via the window 331a. The direction in which the prisms 401, 402 expand and reduce the beam width is a direction perpendicular to the direction in which the electrodes 332a, 332b face each other.

The surface of the output coupling mirror 370 on the beam expander 400 side is coated with a partial reflection film having a predetermined reflectance. The output coupling mirror 370 reflects a part of the laser light from the chamber device CH3 with the beam width thereof expanded by the beam expander 400 toward the beam expander 400, and transmits another part of the laser light.

The output coupling mirror 370 may have a circular shape. The surface of the output coupling mirror 370 on the beam expander 400 side and the surface opposite to the surface may be flat surfaces. Configurations of the rear mirror 371 and the output coupling mirror 370 are similar to that of the output coupling mirror 70.

The rear mirror 371 and the output coupling mirror 370 arranged with the housing 330 interposed therebetween configure a resonator in which the laser light amplified by the electrodes 332a, 332b resonates. The housing 330 and the beam expander 400 are arranged on the optical path of the resonator. The laser light output from the window 331a of the housing 330 is incident on the output coupling mirror 370 via the beam expander 400, and is reflected by the output coupling mirror 370. The laser light reflected by the output coupling mirror 370 returns to the internal space of the housing 330 via the beam expander 400 and the window 331b, and is output from the window 331a. The laser light output from the window 331a is reflected by the rear mirror 371 and returns to the internal space of the housing 330 via the window 331b. Thus, the laser light output from the housing 330 reciprocates between the rear mirror 371 and the output coupling mirror 370. The reciprocating laser light is amplified every time the laser light passes through a laser gain space between the electrode 332a and the electrode 332b. That is, the resonator resonates light between both sides sandwiching the chamber device CH3, and the output coupling mirror 370 is arranged on one side of sandwiching the chamber device CH3. A part of the amplified laser light is transmitted through the output coupling mirror 370. The laser light transmitted through the output coupling mirror 370 travels to the detection unit 153.

The detection unit 153 includes a beam splitter 153b and an optical sensor 153c as a main configuration.

The beam splitter 153b is arranged on the optical path of the laser light transmitted through the output coupling mirror 370. The beam splitter 153b transmits the laser light transmitted through the output coupling mirror 370 toward an output window 173 with a high transmittance, and reflects a part of the pulse laser light toward a light receiving surface of the optical sensor 153c.

The optical sensor 153c measures the pulse energy of the laser light incident on the light receiving surface of the optical sensor 153c. The optical sensor 153c is electrically connected to the processor 190, and outputs a signal indicating the measured pulse energy to the processor 190. The processor 190 controls the voltage to be applied to the electrodes 32a, 32b of the amplifier 160 based on the signal.

The output window 173 is provided on the opposite side of the output coupling mirror 370 with respect to the beam splitter 153b of the detection unit 153. The output window 173 is provided in a wall of the housing 110. The light transmitted through the beam splitter 153b is output from the output window 173 to the exposure apparatus 200 outside the housing 110. The laser light is, for example, pulse laser light having a center wavelength of 193.4 nm.

The display unit 180 is a monitor that displays a state of control by the processor 190 based on a signal from the processor 190. The display unit 180 may be arranged outside the housing 110. The processor 190 of the present disclosure is a processing device including a storage device in which a control program is stored and a central processing unit (CPU) that executes the control program.

The processor 190 is specifically configured or programmed to perform various processes included in the present disclosure. The processor 190 controls the entire gas laser device 100. The processor 190 is electrically connected to an exposure processor (not shown) of the exposure apparatus 200, and transmits and receives various signals to and from the exposure processor.

The laser gas exhaust device 701 and the laser gas supply device 703 are electrically connected to the processor 190. The laser gas exhaust device 701 includes an exhaust pump (not shown), and exhausts the laser gas from the internal spaces of the housings 30, 330 via a pipe by suction of the exhaust pump according to a control signal from the processor 190. The laser gas supply device 703 supplies the laser gas from a laser gas supply source (not shown) arranged outside the housing 110 to the internal spaces of the housings 30, 330 via a pipe according to a control signal from the processor 190.

### 2.2 Operation

Next, operation of the gas laser device 100 of the comparative example will be described.

In a state before the gas laser device 100 outputs the laser light, the laser gas is supplied from the laser gas supply device 703 to the internal spaces of the housings 30, 330.

When the gas laser device 100 outputs the laser light, the processor 190 receives a signal indicating a target energy Et and a light emission trigger signal from the exposure processor (not shown) of the exposure apparatus 200. The target energy Et is a target value of the energy of the laser light to be used in the exposure process. The processor 190 sets a predetermined charge voltage to the charger 41 so that the energy E becomes the target energy Et, and turns ON the switch of the pulse power module 43 in synchronization with the light emission trigger signal. Thus, the pulse power module 43 generates a pulse high voltage from the electric energy held in the charger 41, and applies the high voltage between the electrode 32a and the electrode 32b. When the high voltage is applied, discharge occurs between the electrode 32a and the electrode 32b, the laser medium contained in the laser gas between the electrode 32a and the electrode 32b is brought into an excited state, and light is emitted when the laser medium returns to the ground state. The emitted light resonates between the grating 63 and the output coupling mirror 70, and is amplified every time passing through the discharge space at the internal space of the housing 30, so that laser oscillation occurs. The laser light includes the first linear polarization, and linear polarization whose polarization direction is different from the first linear polarization is reduced from the laser light transmitted through the windows 31a, 31b. A part of the laser light is transmitted through the output coupling mirror 70, is reflected by the high reflection mirrors 141b, 141c, is transmitted through the rear mirror 371 and the window 331b, and travels into the housing 330.

The processor 190 turns ON the switch of the pulse power module 343 so that discharge occurs when the laser light from the laser oscillator 130 travels to the discharge space in the housing 330. That is, the processor 190 controls the pulse power module 343 so that a high voltage is applied to the electrodes 332a, 332b after a predetermined delay time elapses from the timing at which the switch of the pulse power module 43 is turned ON.

Thus, the laser light having entered the amplifier 160 is amplified in the amplifier 160. Further, the laser light having traveled through the internal space of the housing 330 travels to the output coupling mirror 370 via the window 331a and the beam expander 400 as described above, and is reflected by the output coupling mirror 370. The laser light reflected by the output coupling mirror 370 travels through the internal space of the housing 330 via the beam expander 400 and the window 331a, and is output from the window 331b. The light output from the window 331b is reflected by the rear mirror 371 and travels through the internal space of the housing 330 via the window 331b. Thus, the laser light having a predetermined wavelength reciprocates between the rear mirror 371 and the output coupling mirror 370. The laser light includes the first linear polarization, and linear polarization whose polarization direction is different from the first linear polarization is reduced from the laser light when being transmitted through the windows 331a, 331b. Further, the laser light is amplified every time passing through the discharge space at the internal space of the housing 330, and a part of the laser light becomes amplified laser light.

The amplified laser light from the amplifier 160 is transmitted through the output coupling mirror 370 and travels to the beam splitter 153b.

A part of the amplified laser light having traveled to the beam splitter 153b is transmitted through the beam splitter 153b and the output window 173 and travels to the exposure apparatus 200, while another part is reflected by the beam splitter 153b and travels to the optical sensor 153c.

The optical sensor 153c measures the energy E of the received amplified laser light. The optical sensor 153c outputs a signal indicating the measured energy E to the processor 190. The processor 190 performs feedback control on the charge voltages of the chargers 41, 341 so that a difference ΔE between the energy E and the target energy Et is within an allowable range. When the difference DE is within the allowable range, the laser light is transmitted through the beam splitter 153b and the output window 173 and enters the exposure apparatus 200.

### 2.3 Problem

In the comparative example, the beam expander 400 expands the beam width of the laser light output from the chamber device CH3 by the two prisms 401, 402, and outputs the light toward the output coupling mirror 370. Therefore, the energy density of the laser light incident on the output coupling mirror 370 can be reduced, and deterioration of the output coupling mirror 370 over time can be suppressed. However, since the prism 401 and the prism 402 are transmissive optical elements, there is a concern that they deteriorate over time by transmission light. Further, there is a demand for suppressing a decrease in the amount of laser light in the beam expander 400.

Therefore, in the following embodiments, a gas laser device capable of suppressing a decrease in the light amount while suppressing deterioration over time is exemplified.

### 3. Description of Gas Laser Device of First Embodiment

Next, the gas laser device 100 of a first embodiment will be described. Any component same as that described above is denoted by an identical reference sign, and duplicate description thereof is omitted unless specific description is needed. Further, in some drawings, a part of a member may be omitted or simplified for easy viewing.

### 3.1 Configuration

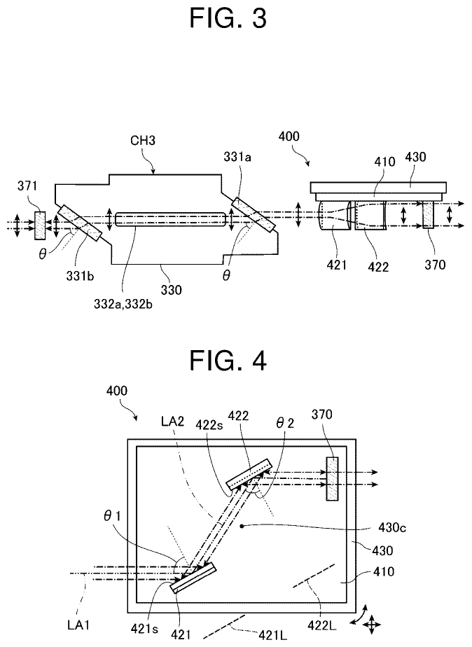

FIG. 3 is a schematic view showing a schematic configuration example of the amplifier 160 according to the first embodiment, and is a schematic view of the amplifier 160 viewed from the electrode 332b side along the direction in which the electrodes 332a, 332b face each other. In FIG. 3, the internal configuration of the chamber device CH3 is shown and the polarization direction of the first linear polarization is indicated by solid arrows. FIG. 4 is a schematic view showing a schematic configuration example of the beam expander 400, and is a schematic view of the beam expander 400 viewed along the polarization direction of the first linear polarization. Therefore, in FIG. 4, a direction perpendicular to the paper surface is the polarization direction of the first linear polarization.

The amplifier 160 of the present embodiment is mainly different from the amplifier 160 of the comparative example in that the beam expander 400 includes a base member 410, a convex mirror 421, a concave mirror 422, and a drive mechanism 430.

The base member 410 is a plate-shaped member extending in a direction parallel to an optical axis LA1 of the laser light output from the window 331a of the chamber device CH3. In the present embodiment, the base member 410 extends in the direction in which the electrodes 332a, 332b face each other, and the output coupling mirror 370 is arranged on one main surface of the base member 410.

The convex mirror 421 includes a reflection surface 421s that reflects light, and reflects the laser light from the chamber device CH3 toward the concave mirror 422. The concave mirror 422 includes a reflection surface 422s that reflects light, and reflects the laser light reflected by the convex mirror 421 toward the output coupling mirror 370. Further, the concave mirror 422 reflects the laser light reflected by the output coupling mirror 370 toward the convex mirror 421, the convex mirror 421 reflects the laser light reflected by the concave mirror 422 toward the chamber device CH3, and the laser light returns to the internal space of the housing 330 via the window 331a. In the present embodiment, the convex mirror 421 and the concave mirror 422 are arranged on the one main surface of the base member 410.

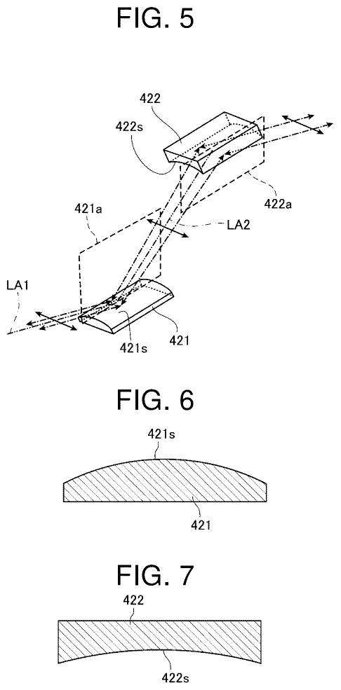

FIG. 5 is a perspective view showing the convex mirror 421 and the concave mirror 422 of the present embodiment. In FIG. 5, the polarization direction of the first linear polarization is indicated by solid arrows. As shown in FIG. 5, in the present embodiment, the convex mirror 421 is a convex cylindrical mirror, and the concave mirror 422 is a concave cylindrical mirror.

FIG. 6 is a sectional view of the convex mirror 421, and the cross section is parallel to a normal line of the reflection surface 421s of the convex mirror 421 and perpendicular to the plane of incidence of the laser light output from the window 331a with respect to the reflection surface 421s. As shown in FIG. 6, the shape of the reflection surface 421s of the convex mirror 421 in the cross section is a curved line, and is an arc in the present embodiment. Here, FIG. 5 shows the plane of incidence 421a of the laser light along the optical axis LA1 with respect to the reflection surface 421s.

FIG. 7 is a sectional view of the concave mirror 422, and the cross section is parallel to a normal line of the reflection surface 422s of the concave mirror 422 and perpendicular to the plane of incidence of the laser light reflected by the convex mirror 421 toward the concave mirror 422 with respect to the reflection surface 422s. As shown in FIG. 7, the shape of the reflection surface 422s of the concave mirror 422 in the cross section is a curved line, and is an arc in the present embodiment. Here, FIG. 5 shows the plane of incidence 422a of the laser light along an optical axis LA2 of the laser light reflected by the convex mirror 421 with respect to the reflection surface 422s.

A focal line 421L of the convex mirror 421 is included in a plane including the optical axis LA1 of the laser light and extending in a direction in which the electrodes 332a, 332b face each other, and is inclined so as to approach the electrode 332a as the distance from the chamber device CH3 increases. Further, a focal line 422L of the concave mirror 422 is included in a plane including the optical axis LA1 of the laser light and the focal line 421L, and is inclined so as to approach the electrode 332a as the distance from the chamber device CH3 increases. The focal line 421L of the convex mirror 421 and the focal line 422L of the concave mirror 422 are located on the same straight line. Further, an incident angle θ1 of the laser light incident on the convex mirror 421 and an incident angle θ2 of the laser light incident on the concave mirror 422 are 45 degrees or more and 85 degrees or less. That is, the positions of the convex mirror 421 and the concave mirror 422 are adjusted as described above. Here, the focal line 421L is a line connecting focal points of the convex mirror 421, and the focal line 422L is a line connecting focal points of the concave mirror 422.

The drive mechanism 430 of the present embodiment includes a rotation mechanism capable of rotating the base member 410 about an axis 430c perpendicular to the extending direction of the base member 410, and a movement mechanism capable of moving the base member 410 in a direction parallel to the extending direction of the base member 410. Therefore, by adjusting the position and orientation of the base member 410 with respect to the chamber device CH3 by the drive mechanism 430, the position and orientation of the convex mirror 421, the concave mirror 422, and the output coupling mirror 370 with respect to the chamber device CH3 can be adjusted. In the drive mechanism 430 of the present embodiment, the rotation mechanism is mounted on the movement mechanism, and the base member 410 is mounted on the rotation mechanism. The axis 430c overlaps the center of gravity of the base member 410, but the position of the axis 430c is not limited thereto.

In the present embodiment, the output coupling mirror 370 has a rectangular shape elongated in the direction perpendicular to the direction in which the electrodes 332a, 332b face each other, and is arranged on one main surface of the base member 410. Here, the shape of the output coupling mirror 370 is not limited, and may be, for example, a circular shape or an elliptical shape.

### 3.2 Operation

When the laser light reciprocating between the rear mirror 371 and the output coupling mirror 370 is transmitted through the windows 331a, 331b, linear polarization whose polarization direction is different from the polarization direction of the first linear polarization is reduced from the laser light. Therefore, most of the polarization components included in the laser light amplified by the amplifier 160 are first linear polarization whose polarization direction is perpendicular to the direction in which the electrodes 332a, 332b face each other, and the polarization direction of the first linear polarization is the direction in which the electrodes 332a, 332b face each other. When the laser light is output from the window 331a of the housing 330, the laser light is reflected by the convex mirror 421 toward the concave mirror 422. The cross section, at the reflection surface 421s, parallel to the normal line of the reflection surface 421s of the convex mirror 421 and perpendicular to the plane of incidence of the laser light output from the window 331a with respect to the reflection surface 421s has an arc shape. Further, the focal line 421L of the convex mirror 421 is included in a plane including the optical axis LA1 of the laser light and extending in a direction in which the electrodes 332a, 332b face each other. Therefore, the laser light output from the window 331a is incident on the reflection surface 421s so that the first linear polarization in the laser light becomes S-polarization, and the beam width of the laser light is expanded in the direction perpendicular to the direction in which the electrodes 332a, 332b face each other. In the present embodiment, since the polarization direction of the first linear polarization is the direction perpendicular to the direction in which the electrodes 332a, 332b face each other, the direction in which the beam width of the laser light is expanded is the same as the polarization direction of the first linear polarization.

The laser light having the expanded beam width is reflected by the concave mirror 422 toward the output coupling mirror 370. The cross section, at the reflection surface 422s, parallel to the normal line of the reflection surface 422s of the concave mirror 422 and perpendicular to the plane of incidence of the laser light whose beam width is expanded with respect to the reflection surface 422s has an arc shape. Further, the focal line 421L of the convex mirror 421 and the focal line 422L of the concave mirror 422 are included in the same plane including the optical axis LA1 of the laser light, and the focal line 421L and the focal line 422L are located on the same straight line. Therefore, the laser light whose beam width is expanded is incident on the reflection surface 422s so that the first linear polarization in the laser light becomes S-polarization, and is reflected to be collimated so that the beam width expanded by the reflection surface 422s becomes constant. Then, the collimated laser light is incident on the output coupling mirror 370.

Further, the laser light reflected by the output coupling mirror 370 is incident on the reflection surface 422s so that the first linear polarization in the laser light becomes S-polarization, and is reflected toward the convex mirror 421 by the reflection surface 422s. The beam width of the laser light is reduced in the direction perpendicular to the direction in which the electrodes 332a, 332b face each other. The laser light having the reduced beam width is incident on the reflection surface 421s so that the first linear polarization in the laser light becomes S-polarization, and is reflected toward the window 331a by the reflection surface 421s. The laser light is collimated so that the reduced beam width becomes constant, and is returned to the internal space of the housing 330 via the window 331a.

### 3.3 Effect

In the amplifier 160 of the present embodiment, each of the windows 331a, 331b of the chamber device CH3 also serves as a polarizer that is inclined with respect to the polarization direction of the first linear polarization and reduces, from the laser light, the linear polarization whose polarization direction is different from the polarization direction of the first linear polarization. Further, the beam expander 400 of the present embodiment includes the convex mirror 421 and the concave mirror 422. The laser light output from the chamber device CH3 is incident on the reflection surface 421s of the convex mirror 421 so that the first linear polarization in the laser light becomes S-polarization, and the reflection surface 421s reflects the laser light so that the beam width of the laser light is expanded. The laser light reflected by the convex mirror 421 is incident on the reflection surface 422s of the concave mirror 422 so that the first linear polarization in the laser light becomes S-polarization, and the reflection surface 422s reflects the laser light toward the output coupling mirror 370 so as to collimate the laser light so that the expanded beam width of the laser light becomes constant. In general, an optical element that reflects light tends to be less likely to deteriorate over time than an optical element that transmits light. Therefore, according to the gas laser device 100 of the present embodiment, as compared with the case in which the beam expander 400 includes the prisms 401, 402 that transmit light, deterioration over time of the beam expander 400 can be suppressed, and as a result, deterioration over time of the gas laser device 100 can be suppressed. Further, in the amplifier 160 of the present embodiment, since the linear polarization being different from the first linear polarization in the laser light is reduced by the windows 331a, 331b as a polarizer, most of the polarization components included in the amplified laser light become the first linear polarization. Such laser light is incident on and reflected by the reflection surface 421s of the convex mirror 421 and the reflection surface 422s of the concave mirror 422 so that the first linear polarization in the laser light becomes S-polarization. The reflectance of S-polarization tends to be higher than that of P-polarization. Therefore, according to the gas laser device 100 of the present embodiment, it is possible to suppress a decrease in the light amount on the reflection surface 421s and the reflection surface 422s as compared, for example, with the case in which the laser light is reflected by being incident on the reflection surface 421s and the reflection surface 422s so that the first linear polarization in the laser light becomes P-polarization. Therefore, according to the gas laser device 100 of the present embodiment, it is possible to suppress a decrease in the light amount while suppressing deterioration over time.

In the amplifier 160 of the present embodiment, the members that reflect the laser light from the chamber device CH3 to the output coupling mirror 370 are only the convex mirror 421 and the concave mirror 422, and the number of times the laser light is reflected is two. Therefore, according to the gas laser device 100 of the present embodiment, the laser light from the chamber device CH3 toward the convex mirror 421 and the laser light from the concave mirror 422 toward the output coupling mirror 370 can be prevented from being reversed by reflection in the beam profile.

The beam expander 400 of the present embodiment further includes the plate-shaped base member 410 extending in a direction parallel to the optical axis LA1 of the laser light from the chamber device CH3 toward the convex mirror 421. The convex mirror 421, the concave mirror 422, and the output coupling mirror 370 are arranged on one main surface of the base member 410. When the convex mirror 421, the concave mirror 422, and the output coupling mirror 370 are to be arranged at the designed position, it may be difficult to secure a working space in the surrounding members. In the present embodiment, by arranging the base member 410 at the designed position, the convex mirror 421, the concave mirror 422, and the output coupling mirror 370 can be arranged at designed positions, respectively. Therefore, according to the gas laser device 100 of the present embodiment, the members can be easily arranged at the designed positions as compared with the case in which the members are to be arranged individually.

In the beam expander 400 of the present embodiment, the focal line 421L of the convex mirror 421 and the focal line 422L of the concave mirror 422 are included in the same plane including the optical axis LA1 of the laser light. Therefore, according to the gas laser device 100 of the present embodiment, the convex mirror 421 and the concave mirror 422 can be easily designed as compared with the case in which the focal line 421L and the focal line 422L are not included in the same plane including the optical axis LA1 of the laser light. Here, at least one of the focal line 421L and the focal line 422L may not be included in the same plane including the optical axis LA1 of the laser light. Further, in the present embodiment, the focal line 421L and the focal line 422L are located on the same straight line, but the focal line 421L and the focal line 422L may not be located on the same straight line.

In the present embodiment, the cross section, at the reflection surface 421s, parallel to the normal line of the reflection surface 421s of the convex mirror 421 and perpendicular to the plane of incidence of the laser light output from the window 331a with respect to the reflection surface 421s has an arc shape. However, the sectional shape of the reflection surface 421s is not limited as long as the laser light output from the chamber device CH3 is incident on the reflection surface 421s so that the first linear polarization in the laser light becomes S-polarization and the reflection surface 421s reflects the laser light so that the beam width of the laser light is expanded. For example, the sectional shape of the reflection surface 421s is simply required to be a curved line, and may be parabolic.

In the present embodiment, the cross section, at the reflection surface 422s, parallel to the normal line of the reflection surface 422s of the concave mirror 422 and perpendicular to the plane of incidence of the laser light reflected by the convex mirror 421 with respect to the reflection surface 422s has an arc shape. However, the sectional shape is not limited as long as the laser light reflected by the convex mirror 421 is incident on the reflection surface 421s so that the first linear polarization in the laser light becomes S-polarization and the reflection surface 421s reflects the laser light toward the output coupling mirror 370 so as to collimate the laser light so that the expanded beam width of the laser light becomes constant. For example, the sectional shape of the reflection surface 422s is simply required to be a curved line, and may be parabolic.

In the present embodiment, the convex mirror 421 reflects the laser light to expand the beam width of the laser light output from the chamber device CH3 in the direction perpendicular to the direction in which the electrodes 332a, 332b face each other. However, the direction in which the beam width is expanded by the convex mirror 421 is not limited. For example, the direction of the beam width expanded by the convex mirror 421 may be the direction in which the electrodes 332a, 332b face each other. The direction of the beam width expanded by the convex mirror 421 may be the same as or different from the polarization direction of the first linear polarization.

In the present embodiment, the polarization direction of the first linear polarization is the direction perpendicular to the direction in which the electrodes 332a, 332b face each other, and the direction of the beam width expanded by the convex mirror 421 is the same as the polarization direction of the first linear polarization. However, the polarization direction of the first linear polarization is not limited. For example, the polarization direction of the first linear polarization may be the direction in which the electrodes 332a, 332b face each other, and the direction of the beam width expanded by the convex mirror 421 may be different from the polarization direction of the first linear polarization.

In the present embodiment, the incident angle θ at which the laser light is incident on the windows 331a, 331b is the Brewster angle. However, the windows 331a, 331b only need to be capable of reducing the linear polarization whose polarization direction is different from the polarization direction of the first linear polarization from the laser light, and the incident angle θ of the laser light is not limited. The windows 331a, 331b may be inclined with respect to the polarization direction of the first linear polarization so that the first linear polarization in the laser light is incident thereon as P-polarization and the incident angle θ of the laser light becomes 25 degrees or more and 75 degrees or less The incident angle θ may be 25 degrees or more and 68 degrees or less. When the incident angle θ is 25 degrees or more and 75 degrees or less, it is possible to reduce the linear polarization whose polarization direction is different from the polarization direction of the first linear polarization. When the incident angle θ is 25 degrees or more and 68 degrees or less, the transmittance of the first linear polarization can be 97% or more, and the linear polarization having a polarization direction different from the polarization direction of the first linear polarization can be more easily reduced from the laser light.

In the present embodiment, the convex mirror 421, the concave mirror 422, and the output coupling mirror 370 are arranged on the base member 410, but the member on which these members are arranged is not limited. For example, each of the convex mirror 421, the concave mirror 422, and the output coupling mirror 370 may be arranged on a different holder. Further, the beam expander 400 may not include the base member 410 and the drive mechanism 430.

In the present embodiment, the incident angle θ1 of the laser light incident on the convex mirror 421 and the incident angle θ2 of the laser light incident on the concave mirror 422 are 45 degrees or more and 85 degrees or less. Due to that the incident angles θ1, θ2 are 45 degrees or more, the energy density of the laser light at the convex mirror 421 and the concave mirror 422 can be hardly increased, and the convex mirror 421 and the concave mirror 422 can be suppressed from being easily deteriorated over time. Further, due to that the incident angles θ1, θ2 are less than 85 degrees, it is possible to suppress the convex mirror 421 and the concave mirror 422 from becoming too large. The incident angles θ1, θ2 may be less than 45 degrees or more than 85 degrees.

### 3.4 Modification

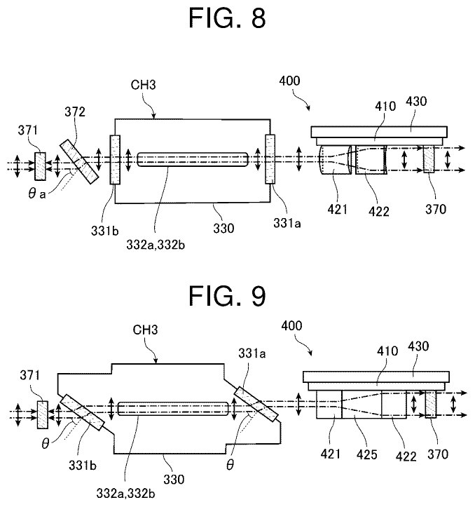

Next, a modification of the present embodiment will be described. FIG. 8 is a schematic view showing a schematic configuration example of the amplifier 160 of the modification of the present embodiment in a similar manner to FIG. 3. As shown in FIG. 8, the amplifier 160 of the present modification is mainly different from the amplifier 160 of the above embodiment in that a polarizer 372 is included and that the windows 331a, 331b are arranged so as to be substantially perpendicular to the travel direction of the laser light.

The polarizer 372 of the present modification is a calcium fluoride substrate similarly to the windows 331a, 331b, and is arranged on the optical path of the resonator between the rear mirror 371 and the window 331b. The surface of the polarizer 372 on the rear mirror 371 side and the surface on the window 331b side are flat surfaces. The polarizer 372 is inclined so as to form the Brewster angle with respect to the polarization direction of the first linear polarization so that the first linear polarization in the laser light is incident thereon as P-polarization and the reflection of the P-polarization is suppressed. Therefore, when the laser light is transmitted through the polarizer 372, linear polarization whose polarization direction is different from the polarization direction of the first linear polarization is reduced from the laser light. Therefore, even in the amplifier 160 of the present modification, most of the polarization components included in the amplified laser light become the first linear polarization. According to the gas laser device 100 of the present modification, flexibility of the configuration of the housing 330 of the chamber device CH3 can be improved as compared with the case in which the linear polarization different from the first linear polarization is reduced from the laser light by the windows 331a, 331b of the chamber device CH3 as in the above embodiment. Here, from the viewpoint of reducing the number of components, as in the above embodiment, it is preferable that each of the windows 331a, 331b also serves as a polarizer that is inclined with respect to the polarization direction of the first linear polarization and reduces, from the laser light, the linear polarization whose polarization direction is different from the polarization direction of the first linear polarization.

The polarizer 372 may be arranged on the optical path of the resonator, for example, between the window 331a and the convex mirror 421 or between the concave mirror 422 and the output coupling mirror 370. The number of polarizers 372 is not limited, and the polarizer 372 may be arranged at at least two or more positions, for example, a position between the rear mirror 371 and the window 331b, a position between the window 331a and the convex mirror 421, and a position between the concave mirror 422 and the output coupling mirror 370. Further, the polarizer 372 is not limited to the calcium fluoride substrate as long as being capable of transmitting the laser light.

The polarizer 372 only needs to be capable of reducing the linear polarization whose polarization direction is different from the polarization direction of the first linear polarization from the laser light, and an incident angle θa at which the laser light is incident on the polarizer 372 is not limited to the Brewster angle. The polarizer 372 may be inclined with respect to the polarization direction of the first linear polarization so that the incident angle θa of the laser light is 25 degrees or more and 75 degrees or less, or may be inclined with respect to the polarization direction of the first linear polarization so that the incident angle θa of the laser light is 25 degrees or more and 68 degrees or less. Owing to that the incident angle θa is 25 degrees or more and 75 degrees or less, it is possible to reduce the linear polarization whose polarization direction is different from the polarization direction of the first linear polarization. Owing to that the incident angle Ga is 25 degrees or more and 68 degrees or less, the transmittance of the first linear polarization can be 97% or more, and the linear polarization whose polarization direction is different from the polarization direction of the first linear polarization can be more easily reduced from the laser light.

### 4. Description of Gas Laser Device of Second Embodiment

Next, the gas laser device 100 of a second embodiment will be described. Any component same as that described above is denoted by an identical reference sign, and duplicate description thereof is omitted unless specific description is needed. Further, in some drawings, a part of a member may be omitted or simplified for easy viewing.

### 4.1 Configuration

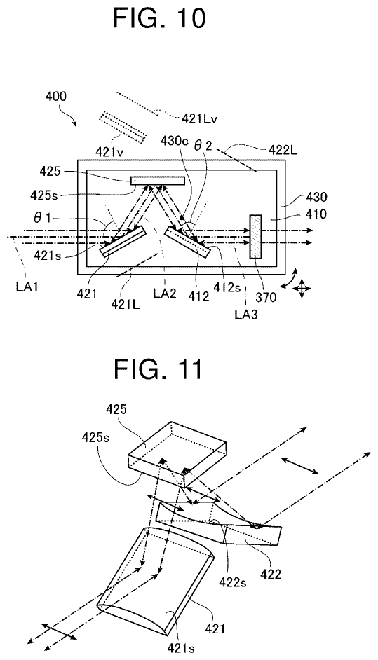

FIG. 9 is a schematic view showing a schematic configuration example of the amplifier 160 of the present embodiment in a similar manner to FIG. 3, and FIG. 10 is a schematic view showing a schematic configuration example of the beam expander 400 of the present embodiment in a similar manner to FIG. 4.

As shown in FIGS. 9 and 10, the amplifier 160 of the present embodiment is mainly different from the amplifier 160 of the first embodiment in that the beam expander 400 further includes a planar mirror 425.

In the present embodiment, the convex mirror 421 reflects the laser light from the chamber device CH3 toward the planar mirror 425. The planar mirror 425 includes a planar reflection surface 425s that reflects light, and reflects the laser light reflected by the convex mirror 421 toward the concave mirror 422. The concave mirror 422 reflects the laser light reflected by the planar mirror 425 toward the output coupling mirror 370. Further, the concave mirror 422 reflects the laser light reflected by the output coupling mirror 370 toward the planar mirror 425, the planar mirror 425 reflects the laser light reflected by the concave mirror 422 toward the convex mirror 421, and the convex mirror 421 reflects the laser light reflected by the planar mirror 425 toward the chamber device CH3. In the present embodiment, the convex mirror 421, the planar mirror 425, the concave mirror 422, and the output coupling mirror 370 are arranged on one main surface of the base member 410.

The focal line 421L of the convex mirror 421 is included in a plane including the optical axis LA1 of the laser light and extending in a direction in which the electrodes 332a, 332b face each other, and is inclined so as to approach the electrode 332a as the distance from the chamber device CH3 increases. Further, the focal line 422L of the concave mirror 422 is included in a plane including the optical axis LA1 of the laser light and the focal line 421L, and is inclined so as to approach the electrode 332b as the distance from the chamber device CH3 increases. Then, a focal line 421Lv of a virtual image 421v of the convex mirror 421 formed by the reflection surface 425s of the planar mirror 425 and the focal line 422L of the concave mirror 422 are located on the same straight line. Further, the optical axis LA1 of the laser light from the chamber device CH3 toward the convex mirror 421 and an optical axis LA3 of the laser light from the concave mirror 422 toward the output coupling mirror 370 are located on the same straight line. Further, the incident angle θ1 of the laser light incident on the convex mirror 421 and the incident angle θ2 of the laser light incident on the concave mirror 422 are 45 degrees or more and 85 degrees or less. That is, the positions of the convex mirror 421, the planar mirror 425, and the concave mirror 422 are adjusted as described above. In FIG. 10, the virtual image 421v and the focal line 421Lv of the virtual image 421v are indicated by broken lines.

### 4.2 Operation

FIG. 11 is a perspective view showing the convex mirror 421, the planar mirror 425, and the concave mirror 422 of the present embodiment in a similar manner to FIG. 5. Similarly to the first embodiment, the laser light output from the window 331a is incident on the reflection surface 421s of the convex mirror 421 so that the first linear polarization in the laser light becomes S-polarization, and the beam width of the laser light is expanded in the direction perpendicular to the direction in which the electrodes 332a, 332b face each other. The direction in which the beam width of the laser light is expanded is the same as the polarization direction of the first linear polarization.

The laser light having the expanded beam width is incident on the reflection surface 425s of the planar mirror 425 so that the first linear polarization in the laser light becomes S-polarization, and is reflected toward the concave mirror 422 by the reflection surface 425s. As described above, the focal line 421Lv of the virtual image 421v and the focal line 422L of the concave mirror 422 are located on the same straight line. Therefore, the laser light reflected by the planar mirror 425 is incident on the reflection surface 422s of the concave mirror 422 so that the first linear polarization in the laser light becomes S-polarization, and is reflected to be collimated so that the beam width expanded by the reflection surface 422s becomes constant. Then, the collimated laser light is incident on the output coupling mirror 370.

Further, the laser light reflected by the output coupling mirror 370 is incident on the reflection surface 422s so that the first linear polarization in the laser light becomes S-polarization, and is reflected toward the planar mirror 425 by the reflection surface 422s. The beam width of the laser light is reduced in the direction perpendicular to the direction in which the electrodes 332a, 332b face each other. The laser light having the reduced beam width is incident on the reflection surface 425s so that the first linear polarization in the laser light becomes S-polarization, and is reflected toward the convex mirror 421 by the reflection surface 425s. The laser light reflected by the reflection surface 425s is incident on the reflection surface 421s so that the first linear polarization in the laser light becomes S-polarization, and is reflected toward the window 331a by the reflection surface 421s. The laser light is collimated so that the reduced beam width becomes constant, and is returned to the internal space of the housing 330 via the window 331a.

### 4.3 Effect

In the beam expander 400 of the present embodiment, as described above, the laser light output from the chamber device CH3 is reflected in the order of the convex mirror 421, the planar mirror 425, and the concave mirror 422, and the beam width of the laser light is expanded. Then, the laser light whose beam width is expanded is incident on the output coupling mirror 370. Therefore, according to the gas laser device 100 of the present embodiment, as compared with the case in which the beam expander 400 includes the prisms 401, 402 that transmit light, deterioration over time of the beam expander 400 can be suppressed. Further, according to the gas laser device 100 of the present embodiment, it is possible to suppress a decrease in the light amount on the reflection surface 421s, the reflection surface 425s, and the reflection surface 422s as compared, for example, with the case in which the laser light is reflected by being incident on the reflection surface 421s, the reflection surface 425s, and the reflection surface 422s so that the first linear polarization in the laser light becomes P-polarization. Further, according to the gas laser device 100 of the present embodiment, it is possible to suppress the beam expander 400 from being enlarged in a direction in which the convex mirror 421 reflects the laser light from the chamber device CH3 as compared with the case in which the planar mirror 425 is not included.

In the beam expander 400 of the present embodiment, the convex mirror 421, the planar mirror 425, the concave mirror 422, and the output coupling mirror 370 are arranged on one main surface of the base member 410. Therefore, by arranging the base member 410 at the designed position, the convex mirror 421, the planar mirror 425, the concave mirror 422, and the output coupling mirror 370 can be arranged at the designed positions, respectively. Therefore, according to the gas laser device 100 of the present embodiment, the members can be easily arranged at the designed positions as compared with the case in which the members are to be arranged individually. Here, the member on which these members are arranged is not limited. For example, each of the convex mirror 421, the planar mirror 425, the concave mirror 422, and the output coupling mirror 370 may be arranged on a different holder. Further, the beam expander 400 may not include the base member 410 and the drive mechanism 430.

In the present embodiment, the focal line 421Lv of the virtual image 421v formed by the reflection surface 425s of the planar mirror 425 and the focal line 422L of the concave mirror 422 are located on the same straight line, but the focal line 421Lv and the focal line 422L may not be located on the same straight line.

In the present embodiment, the optical axis LA1 of the laser light from the chamber device CH3 toward the convex mirror 421 and the optical axis LA3 of the laser light from the concave mirror 422 toward the output coupling mirror 370 are located on the same straight line. Therefore, for example, the beam expander 400 may be arranged in the conventional amplifier 160 without changing the designed positions of the chamber device CH3 and the output coupling mirror 370. Here, the optical axis LA1 and the optical axis LA3 may not be located on the same straight line.

In the present embodiment, similarly to the first embodiment, the incident angle θ1 of the laser light incident on the convex mirror 421 and the incident angle θ2 of the laser light incident on the concave mirror 422 are 45 degrees or more and 85 degrees or less. Therefore, it is possible to suppress the convex mirror 421 and the concave mirror 422 from being easily deteriorated over time, and to suppress the convex mirror 421 and the concave mirror 422 from becoming too large. The incident angles θ1, θ2 may be less than 45 degrees or more than 85 degrees. The incident angle of the laser light incident on the planar mirror 425 may be 45 degrees or more and 85 degrees or less, may be less than 45 degrees, or may be more than 85 degrees.

### 5. Description of Gas Laser Device of Third Embodiment

Next, the gas laser device 100 of a third embodiment will be described. Any component same as that described above is denoted by an identical reference sign, and duplicate description thereof is omitted unless specific description is needed. Further, in some drawings, a part of a member may be omitted or simplified for easy viewing.

### 5.1 Configuration

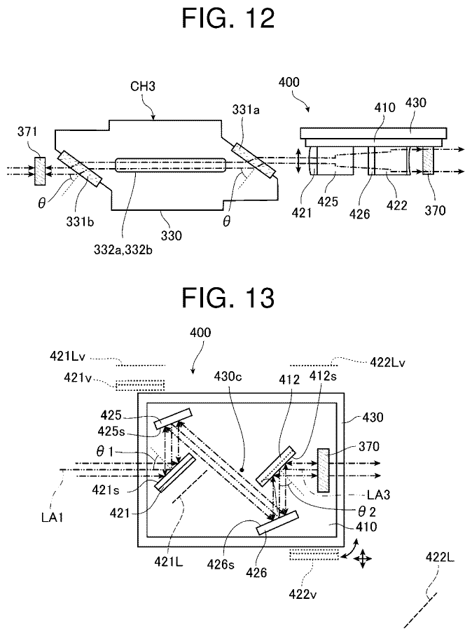

FIG. 12 is a schematic view showing a schematic configuration example of the amplifier 160 of the present embodiment in a similar manner to FIG. 3, and FIG. 13 is a schematic view showing a schematic configuration example of the beam expander 400 of the present embodiment in a similar manner to FIG. 4.

As shown in FIGS. 12 and 13, the amplifier 160 of the present embodiment is mainly different from the amplifier 160 of the second embodiment in that the beam expander 400 further includes a planar mirror 426.

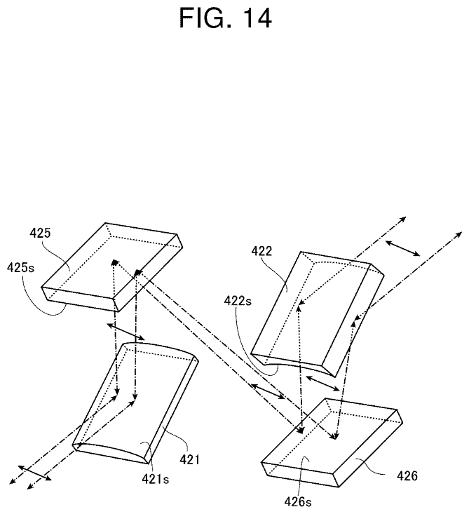

FIG. 14 is a perspective view showing the convex mirror 421, the two planar mirrors 425, 426, and the concave mirror 422 of the present embodiment in a similar manner to FIG. 5. Hereinafter, the planar mirror 425 is referred to as a first planar mirror, and the planar mirror 426 is referred to as a second planar mirror. In the present embodiment, the convex mirror 421 reflects the laser light from the chamber device CH3 toward the first planar mirror 425. The first planar mirror 425 includes a planar reflection surface 425s that reflects light, and reflects the laser light reflected by the convex mirror 421 toward the second planar mirror 426. The second planar mirror 426 includes a planar reflection surface 426s that reflects light, and reflects the laser light reflected by the first planar mirror 425 toward the concave mirror 422. The concave mirror 422 reflects the laser light reflected by the second planar mirror 426 toward the output coupling mirror 370. The concave mirror 422 reflects the laser light reflected by the output coupling mirror 370 toward the second planar mirror 426, and the second planar mirror 426 reflects the laser light reflected by the concave mirror 422 toward the first planar mirror 425. The first planar mirror 425 reflects the laser light reflected by the second planar mirror 426 toward the convex mirror 421, and the convex mirror 421 reflects the laser light reflected by the first planar mirror 425 toward the chamber device CH3. In the present embodiment, the convex mirror 421, the first planar mirror 425, the second planar mirror 426, the concave mirror 422, and the output coupling mirror 370 are arranged on one main surface of the base member 410.

The focal line 421L of the convex mirror 421 is included in the plane including the optical axis LA1 of the laser light and extending in the direction in which the electrodes 332a, 332b face each other, and is inclined so as to approach the electrode 332a as the distance from the chamber device CH3 increases. Further, the focal line 422L of the concave mirror 422 is included in the plane including the optical axis LA1 of the laser light and the focal line 421L, and is inclined so as to approach the electrode 332b as the distance from the chamber device CH3 increases. Then, the focal line 421Lv of the virtual image 421v of the convex mirror 421 formed by the reflection surface 425s of the first planar mirror 425 and a focal line 422Lv of a virtual image 422v of the concave mirror 422 formed by the reflection surface 426s of the second planar mirror 426 are located on the same straight line. Further, the optical axis LA1 of the laser light from the chamber device CH3 toward the convex mirror 421 and the optical axis LA3 of the laser light from the concave mirror 422 toward the output coupling mirror 370 are located on the same straight line. That is, the positions of the convex mirror 421, the planar mirror 425, and the concave mirror 422 are adjusted as described above. In FIG. 13, the virtual image 421v, the focal line 421Lv of the virtual image 421v, the virtual image 422v, and the focal line 422Lv of the virtual image 422v are indicated by broken lines.

### 5.2 Operation

Similarly to the second embodiment, the laser light output from the window 331a is incident on the reflection surface 421s of the convex mirror 421 so that the first linear polarization in the laser light becomes S-polarization, and the beam width of the laser light is expanded in the direction perpendicular to the direction in which the electrodes 332a, 332b face each other. The direction in which the beam width of the laser light is expanded is the same as the polarization direction of the first linear polarization.

The laser light having the expanded beam width is incident on the reflection surface 425s of the first planar mirror 425 so that the first linear polarization in the laser light becomes S-polarization, and is reflected toward the second planar mirror 426 by the reflection surface 425s. The laser light reflected by the first planar mirror 425 is incident on the reflection surface 426s of the second planar mirror 426 so that the first linear polarization in the laser light becomes S-polarization, and is reflected toward the concave mirror 422 by the reflection surface 426s. As described above, the focal line 421Lv of the virtual image 421v and the focal line 422Lv of the virtual image 422v are located on the same straight line. Therefore, the laser light reflected by the second planar mirror 426 is incident on the reflection surface 422s of the concave mirror 422 so that the first linear polarization in the laser light becomes S-polarization, and is reflected to be collimated so that the beam width expanded by the reflection surface 422s becomes constant. Then, the collimated laser light is incident on the output coupling mirror 370.

Further, the laser light reflected by the output coupling mirror 370 is incident on the reflection surface 422s so that the first linear polarization in the laser light becomes S-polarization, and is reflected toward the second planar mirror 426 by the reflection surface 422s. The beam width of the laser light is reduced in the direction perpendicular to the direction in which the electrodes 332a, 332b face each other. The laser light having the reduced beam width is incident on the reflection surface 426s so that the first linear polarization in the laser light becomes S-polarization, and is reflected toward the first planar mirror 425 by the reflection surface 426s. The laser light reflected by the reflection surface 426s is incident on the reflection surface 425s so that the first linear polarization in the laser light becomes S-polarization, and is reflected toward the concave mirror 422 by the reflection surface 425s. The laser light reflected by the reflection surface 425s is incident on the reflection surface 421s so that the first linear polarization in the laser light becomes S-polarization, and is reflected toward the window 331a by the reflection surface 421s. The laser light is collimated so that the reduced beam width becomes constant, and is returned to the internal space of the housing 330 via the window 331a.

### 5.3 Effect

In the beam expander 400 of the present embodiment, as described above, the laser light output from the chamber device CH3 is reflected in the order of the convex mirror 421, the first planar mirror 425, the second planar mirror 426, and the concave mirror 422, and the beam width of the laser light is expanded. Then, the laser light whose beam width is expanded is incident on the output coupling mirror 370. Therefore, according to the gas laser device 100 of the present embodiment, as compared with the case in which the beam expander 400 includes the prisms 401, 402 that transmit light, deterioration over time of the beam expander 400 can be suppressed. Further, according to the gas laser device 100 of the present embodiment, it is possible to suppress a decrease in the light amount on the reflection surface 421s, the reflection surface 425s, the reflection surface 426s, and the reflection surface 422s as compared, for example, with the case in which the laser light is reflected by being incident on the reflection surface 421s, the reflection surface 425s, the reflection surface 426s, and the reflection surface 422s so that the first linear polarization in the laser light becomes P-polarization.

In the beam expander 400 of the present embodiment, the convex mirror 421, the first planar mirror 425, the second planar mirror 426, the concave mirror 422, and the output coupling mirror 370 are arranged on one main surface of the base member 410. Therefore, by arranging the base member 410 at the designed position, the convex mirror 421, the first planar mirror 425, the second planar mirror 426, the concave mirror 422, and the output coupling mirror 370 can be arranged at the designed positions, respectively. Therefore, according to the gas laser device 100 of the present embodiment, the members can be easily arranged at the designed positions as compared with the case in which the members are to be arranged individually. Here, the member on which these members are arranged is not limited. For example, each of the convex mirror 421, the first planar mirror 425, the second planar mirror 426, the concave mirror 422, and the output coupling mirror 370 may be arranged on a different holder. Further, the beam expander 400 may not include the base member 410 and the drive mechanism 430.

In the amplifier 160 of the present embodiment, the members that reflect the laser light from the chamber device CH3 to the output coupling mirror 370 are only the convex mirror 421, the first planar mirror 425, the second planar mirror 426, and the concave mirror 422, and the number of times the laser light is reflected is four. Therefore, according to the gas laser device 100 of the present embodiment, the laser light from the chamber device CH3 toward the convex mirror 421 and the laser light from the concave mirror 422 toward the output coupling mirror 370 can be prevented from being reversed by reflection in the beam profile.

In the present embodiment, the focal line 421Lv of the virtual image 421v and the focal line 422Lv of the virtual image 422v are located on the same straight line, but the focal line 421Lv and the focal line 422Lv may not be located on the same straight line.

In the present embodiment, the optical axis LA1 of the laser light from the chamber device CH3 toward the convex mirror 421 and the optical axis LA3 of the laser light from the concave mirror 422 toward the output coupling mirror 370 are located on the same straight line. Therefore, for example, the beam expander 400 may be arranged in the conventional amplifier 160 without changing the designed positions of the chamber device CH3 and the output coupling mirror 370. Here, the optical axis LA1 and the optical axis LA3 may not be located on the same straight line.

Further, similarly to the first embodiment, the incident angle of the laser light incident on the convex mirror 421 and the incident angle of the laser light incident on the concave mirror 422 may be 45 degrees or more and 85 degrees or less, may be less than 45 degrees, or may be more than 85 degrees. Further, the incident angle of the laser light incident on the first planar mirror 425 and the incident angle of the laser light incident on the second planar mirror 426 may be 45 degrees or more and 85 degrees or less, may be less than 45 degrees, or may be more than 85 degrees.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of the any thereof and any other than A, B, and C.

What is claimed is:

1. A gas laser device configured to amplify, using an amplifier, laser light output from a laser oscillator and output the laser light,
the amplifier comprising:
a chamber device including a pair of discharge electrodes facing each other and arranged at an internal space thereof through which the laser light from the laser oscillator passes and in which a laser gas is filled, and configured to amplify the laser light from the laser oscillator by a voltage being applied between the pair of discharge electrodes;
a resonator configured to cause the laser light output from the chamber device to resonate between both sides sandwiching the chamber device;
a polarizer arranged on an optical path of the laser light of the resonator, and configured to reduce, from the laser light, linear polarization whose polarization direction is different from a polarization direction of a first linear polarization; and
a beam expander,
the resonator including an output coupling mirror arranged on one side of the sides sandwiching the chamber device, and configured to cause a part of the laser light output from the chamber device to be transmitted therethrough, and another part of the laser light output from the chamber device to be reflected to return into the chamber device, and
the beam expander being arranged between the chamber device and the output coupling mirror, and including:
a convex mirror including a reflection surface on which the laser light output from the chamber device is incident so that the first linear polarization in the laser light becomes S-polarization, and which reflects the laser light so that a beam width of the laser light is expanded; and
a concave mirror including a reflection surface on which the laser light reflected by the convex mirror is incident so that the first linear polarization in the laser light becomes S-polarization, and which reflects the laser light toward the output coupling mirror so as to collimate the laser light so that the expanded beam width of the laser light becomes constant.

2. The gas laser device according to claim 1,
wherein the polarizer is a calcium fluoride substrate.

3. The gas laser device according to claim 2,
wherein the chamber device includes a window through which the laser light is transmitted, and
the window is inclined with respect to the polarization direction of the first linear polarization and also serves as the polarizer.

4. The gas laser device according to claim 3,
wherein an incident angle of the laser light incident on the window is 25 degrees or more and 75 degrees or less.

5. The gas laser device according to claim 1,
wherein the beam expander further includes a plate-shaped base member extending in a direction parallel to an optical axis of the laser light from the chamber device toward the convex mirror, and having a main surface on which the convex mirror, the concave mirror, and the output coupling mirror are arranged.

6. The gas laser device according to claim 1,
wherein the beam expander further includes a planar mirror including a reflection surface on which the laser light reflected by the convex mirror is incident so that the first linear polarization in the laser light becomes S-polarization, and which reflects the laser light toward the concave mirror.

7. The gas laser device according to claim 6,
wherein the beam expander further includes a plate-shaped base member extending in a direction parallel to an optical axis of the laser light from the chamber device toward the convex mirror and having a main surface on which the convex mirror, the planar mirror, and the concave mirror are arranged.

8. The gas laser device according to claim 7,
wherein the optical axis of the laser light from the chamber device toward the convex mirror and an optical axis of the laser light from the concave mirror toward the output coupling mirror are located on a same straight line.

9. The gas laser device according to claim 1,
wherein the beam expander further includes:
a first planar mirror including a reflection surface on which the laser light reflected by the convex mirror is incident so that the first linear polarization in the laser light becomes S-polarization, and which reflects the laser light; and
a second planar mirror including a reflection surface on which the laser light reflected by the first planar mirror is incident so that the first linear polarization in the laser light becomes S-polarization, and which reflects the laser light toward the concave mirror.

10. The gas laser device according to claim 9,
wherein the beam expander further includes a plate-shaped base member extending in a direction parallel to an optical axis of the laser light from the chamber device toward the convex mirror, and having a main surface on which the convex mirror, the first planar mirror, the second planar mirror, the concave mirror, and the output coupling mirror are arranged.

11. The gas laser device according to claim 9,
wherein an optical axis of the laser light from the chamber device toward the convex mirror and an optical axis of the laser light from the concave mirror toward the output coupling mirror are located on a same straight line.

12. The gas laser device according to claim 1,
wherein a sectional shape, at the reflection surface of the convex mirror, parallel to a normal line of the reflection surface and perpendicular to a plane of incidence of the laser light with respect to the reflection surface of the convex mirror, and a sectional shape, at the reflection surface of the concave mirror, parallel to a normal line of the reflection surface and perpendicular to a plane of incidence of the laser light with respect to the reflection surface of the concave mirror are each a curved line.

13. The gas laser device according to claim 12,
wherein the sectional shape at the reflection surface of the convex mirror and the sectional shape at the reflection surface of the concave mirror are each an arc.

14. The gas laser device according to claim 1,
wherein an incident angle of the laser light incident on the convex mirror and an incident angle of the laser light incident on the concave mirror are each 45 degrees or more.

15. The gas laser device according to claim 1,
wherein an incident angle of the laser light incident on the convex mirror and an incident angle of the laser light incident on the concave mirror are each 85 degrees or less.

16. The gas laser device according to claim 1,
wherein the polarization direction of the first linear polarization is a direction perpendicular to a direction in which the pair of discharge electrodes face each other.

17. The gas laser device according to claim 1,
wherein the convex mirror reflects the laser light to expand the beam width of the laser light output from the chamber device in a direction perpendicular to a direction in which the pair of discharge electrodes face each other.

18. The gas laser device according to claim 1,
wherein the convex mirror reflects the laser light to expand the beam width of the laser light output from the chamber device in a direction parallel to the polarization direction of the first linear polarization.

19. An electronic device manufacturing method, comprising:
generating pulse laser light using a gas laser device;
outputting the pulse laser light to an exposure apparatus; and
exposing a photosensitive substrate to the pulse laser light in the exposure apparatus to manufacture an electronic device,
the gas laser device being configured to amplify, using an amplifier, laser light output from a laser oscillator and output the laser light,
the amplifier comprising:
a chamber device including a pair of discharge electrodes facing each other and arranged at an internal space thereof through which the laser light from the laser oscillator passes and in which a laser gas is filled, and configured to amplify the laser light from the laser oscillator by a voltage being applied between the pair of discharge electrodes;
a resonator configured to cause the laser light output from the chamber device to resonate between both sides sandwiching the chamber device;
a polarizer arranged on an optical path of the laser light of the resonator, and configured to reduce, from the laser light, linear polarization whose polarization direction is different from a polarization direction of a first linear polarization; and
a beam expander,
the resonator including an output coupling mirror arranged on one side of the sides sandwiching the chamber device, and configured to cause a part of the laser light output from the chamber device to be transmitted therethrough, and another part of the laser light output from the chamber device to be reflected to return into the chamber device, and
the beam expander being arranged between the chamber device and the output coupling mirror, and including:
a convex mirror including a reflection surface on which the laser light output from the chamber device is incident so that the first linear polarization in the laser light becomes S-polarization, and which reflects the laser light so that a beam width of the laser light is expanded; and
a concave mirror including a reflection surface on which the laser light reflected by the convex mirror is incident so that the first linear polarization in the laser light becomes S-polarization, and which reflects the laser light toward the output coupling mirror so as to collimate the laser light so that the expanded beam width of the laser light becomes constant.
